(19) United States
(12) Patent Application Publication
(10) Pub. No.: US 2012/0073658 A1
(43) Pub. Date: Mar. 29, 2012

(54) Solar Cell and Method for Fabricating the Same

(75) Inventor: Takashi TOMITA, Nara-shi (JP)

(73) Assignee: Takashi Tomita, Nara-shi (JP)

(21) Appl. No.: 13/222,489

(22) Filed: Aug. 31, 2011

(30) Foreign Application Priority Data
Sep. 1, 2010 (JP) 2010-196087

(51) Int. Cl. H01L 31/0264; H01L 31/18

(52) U.S. Cl. 136/261; 136/252; 136/262; 438/94; 257/E31.005

(57) ABSTRACT

In a heterojunction solar cell, a semiconductor A is bonded to a different conductivity type semiconductor B having an electron affinity a₂ which is larger than an electron affinity a₁ of the semiconductor A. The semiconductor A and the semiconductor B are lattice-matched to each other with a mismatch ratio of less than 1%, respectively. In a method for fabricating the heterojunction solar cell, the semiconductor A and the semiconductor B are lattice-matched to each other with a mismatch ratio of less than 1% respectively, and the semiconductor A is made of p-type silicon with a p-type germanium layer formed on the surface thereof, and n-type GaP is formed after removing an oxide film by removing the germanium layer.

### BACKGROUND OF THE INVENTION

1. Field of the Invention

The present invention relates to a novel solar cell and a method for fabricating the same.

2. Description of the Related Art

Sunlight has a wide spectrum distribution ranging from near infrared light to ultraviolet light with its energy peak in the vicinity of the green light band. It is known that the band width of a semiconductor is preferably within a peak band of the sunlight spectrum so as to obtain a solar cell having high quantum efficiency.

In a semiconductor having a band width larger than green light, carriers generated by photo-excitation are unlikely to recombine, whereby the open-circuit voltage can be easily increased and thereby the operating voltage for getting maximum output can be increased. It is known that a semiconductor having a band width larger than silicon, for example, a semiconductor such as GaAs, is used to obtain a solar cell having high efficiency.

On the other hand, as a semiconductor material for fabricating a solar cell, silicon is used widely, while germanium, which is a single Group IV element semiconductor same as silicon, is not used so much. One of the reasons is that the band width of germanium is 0.65 eV, and the open circuit voltage of a p-n junction germanium solar cell is low at 0.27 V, which makes it difficult to fabricate a solar cell having high output.

On the other hand, the band width of silicon is 1.1 eV and a p-n junction silicon solar cell provides the open circuit voltage of 0.6 to 0.65 V.

Consequently, a semiconductor having a small band width like germanium has a high probability that electrons and holes generated by photo-excitation recombine each other and thereby increase the reverse direction saturation current flowing through the p-n junction for providing solar cell characteristics, which in turn reduces the open circuit voltage. However, when a germanium semiconductor having a small band width is used, a wide band ranging from the long wavelength band, in which sunlight cannot be absorbed by silicon, to the short wave band can be utilized, so that a large short circuit current can be obtained.

For the purpose of obtaining a high efficiency solar cell as described above, it is preferable to use a semiconductor having a small band width to get a large short circuit current, while it is preferable to use a semiconductor having a large band width to get a large open circuit voltage. Consequently, under the phenomena contrary to each other, a multi-junction solar cell is effective in solving the technical problem of achieving high efficiency.

As a method to efficiently convert, to electric energy, sunlight in several sub-bands divided from the wavelength band of the sunlight spectrum, a multi-junction solar cell is being fabricated. The multi-junction solar cell has a stack structure formed by the p-n junction of semiconductors of several types, i.e. semiconductors having different band widths. To increase the number of multi-junctions, combination of semiconductors lattice-matched to each other is preferable.

Presently, a typical multi-junction solar cell is formed by tunneling a p-n junction germanium solar cell, a p-n junction InGaAs solar cell and a p-n junction InGaP solar cell respectively. The stack structure is epitaxially grown on the germanium substrate sequentially by the MOCVD method. Accordingly, fabrication of the multi-junction solar cell needs repetition of high-degree semiconductor growth at high costs.

When fabricating a solar cell using a semiconductor having a small band width like germanium, if the p-n junction is formed by, for example, a commonly used diffusion method shown in FIG. 3, surface state and crystal defects resulting from the crystalline discontinuity on the surface cause electrons (05) and holes (06) excited by light irradiation to diffuse toward an n-type semiconductor (07) and a p-type semiconductor (08) respectively. Thereafter, however, recombining of electrons (05) and holes (06) is promoted and thereby the reverse direction saturation current increases. As a result, the open circuit voltage cannot be increased.

It is well known that surface state density can be reduced by forming a window layer using semiconductors of different types. When forming semiconductors of different types, there is a problem that selection and combination of such semiconductors is limited due to a significant stress applied to an interface therebetween, which is likely to causes lattice defects at the interface. Since barriers are created due to the band discontinuity caused when forming a heterojunction, there is a problem that photo-excited carriers stay and recombine increasingly. Consequently, the heterojunction solar cell is not used widely due to its fabrication difficulty.

### SUMMARY OF THE INVENTION

According to an aspect of the present invention in a heterojunction solar cell, a semiconductor A is bonded to a semiconductor B of a conductivity type different from a conductivity type of the semiconductor A and having an electron affinity a₂ which is larger than an electron affinity a₁ of the semiconductor A, and the semiconductor A and the semiconductor B are lattice-matched to each other with a mismatch ratio of less than 1% respectively.

According to an aspect of the present invention in a heterojunction solar cell, the semiconductor A is a Group IV semiconductor, and the semiconductor B is a Group III-V compound semiconductor.

According to an aspect of the present invention in a heterojunction solar cell, the semiconductor A is a p-type indirect transition type semiconductor, and the semiconductor B is an n-type direct transition type semiconductor.

According to an aspect of the present invention in a heterojunction solar cell, the semiconductor A is made of p-type germanium, and the semiconductor B is made of n-type InGaP.

According to an aspect of the present invention in a heterojunction solar cell, the composition ratio of the In and the Ga is 49% and 51% respectively.

According to an aspect of the present invention in a heterojunction solar cell, the hole carrier concentration of the p-type germanium is controlled to 10¹⁸ cm⁻³.

According to an aspect of the present invention in a heterojunction solar cell, the semiconductor A is made of p-type silicon, and the semiconductor B is a mixed crystal comprising n-type GaP as a primary component.

According to an aspect of the present invention in a heterojunction solar cell, the nitrogen doping level in the GaP is 0.2%, and GaP and Si are lattice-matched to each other with a mismatch ratio of less than 0.1% respectively.

According to an aspect of the present invention in a heterojunction solar cell, the semiconductor A is a p-type mixed crystal comprising silicon and germanium, and the semiconductor B is a mixed crystal of n-type compound semiconductors.

According to an aspect of the present invention in a heterojunction solar cell, the semiconductor A is formed by p-type silicon carbide with n-type AIN formed on the surface thereof.

According to an aspect of the present invention in a heterojunction solar cell, the semiconductor A is made of p-type silicon with a p-type germanium layer formed on the surface thereof, and n-type GaP is formed thereon after removing an oxide film by removing the germanium layer.

According to an aspect of the present invention in a method for fabricating a heterojunction solar cell in which a semiconductor A is bonded to a semiconductor B of a conductivity type different from a conductivity type of the semiconductor A and having an electron affinity which is larger than an electron affinity of the semiconductor A, and the semiconductor A and the semiconductor B are lattice-matched to each other with a mismatch ratio of less than 1% respectively, the semiconductor A is made of p-type silicon with a p-type germanium layer formed on the surface thereof, and n-type GaP is formed after removing an oxide film by removing the germanium layer.

According to an aspect of the present invention in a method for fabricating a heterojunction solar cell, the semiconductor A is made of p-type silicon, and the semiconductor B is a mixed crystal comprising n-type GaP as a primary component.

According to an aspect of the present invention in a method for fabricating a heterojunction solar cell, the nitrogen doping level in the GaP is 0.2%, and GaP and Si are lattice-matched to each other with a mismatch ratio of less than 0.1% respectively.

According to an aspect of the present invention in a method for fabricating a heterojunction solar cell, a semiconductor A is formed by p-type silicon carbide with n-type AIN formed on the surface thereof.

According to an aspect of the present invention in a method for fabricating a heterojunction solar cell, the semiconductor A is made of p-type silicon with a p-type germanium layer formed on the surface thereof, and n-type GaP is formed after removing an oxide film by removing the germanium layer.

FIG. 1 is a diagram illustrating the principle of a solar cell according to the present invention.

Defects at an interface (9) of the heterojunction provides a structure wherein minority carriers generated by irradiation of sunlight are moved to a region in which respective minority carriers belong to majority carriers, so as to minimize recombining of the minority carriers and suppress recombining of the photo-excited carriers and thereby prevent increase of the reverse direction saturation current. At that time, an n-type semiconductor (02) having a large electron affinity and a large forbidden band width is stacked on a p-type semiconductor substrate (01) having a small electron affinity. A negative electrode (03) is arranged on the n-type semiconductor substrate (02), and a positive electrode (04) is arranged on the p-type semiconductor substrate (01). The negative electrode (03) and the positive electrode (04) are formed on the n-type semiconductor layer (02) and the p-type semiconductor layer (01) respectively. By adopting such configuration, prompt movement of holes is promoted and occurrence of recombining is prevented, so that the problem can be solved.

A diagram further illustrating the principle of a solar cell according to the present invention is shown in FIG. 2.

A solar cell according to the present invention is configured to promptly move photo-excited carriers, especially holes. A semiconductor of a different type is arranged on one of semiconductors so that holes having a large effective mass can be moved promptly due to the band discontinuity.

Accordingly, a semiconductor having a large band width and a large electron affinity is formed on the surface to provide a large electric potential energy. Especially, in the case of a single element semiconductor such as silicon and germanium, a semiconductor having a large electron affinity is arranged on a window layer to promptly transport holes having an especially low mobility to a p-type semiconductor layer in which the hole is a majority carrier, by utilizing the electric potential discontinuity so as to suppress recombining.

With the structure described above, a solar cell using a semiconductor having a small band width can prevent recombining of photo-excited carriers and thereby achieve a large open circuit voltage. The open circuit voltage of conventional p-n junction solar cells is 0.27 V, while the open circuit voltage of a heterojunction solar cell according to the present invention is 0.55 to 0.71 V. A solar cell having high conversion efficiency can be obtained by increasing the open circuit voltage.

Also, the open circuit voltage of conventional p-n junction silicon solar cells is 0.6 to 0.65 V, while the open circuit voltage of a silicon heterojunction solar cell according to the present invention is 0.8 to 0.9 V.

### BRIEF DESCRIPTION OF THE DRAWINGS

Embodiments of the present invention will be described in detail based on the following drawings, wherein:

FIG. 1 is a basic illustrative diagram of a solar cell according to the present invention;

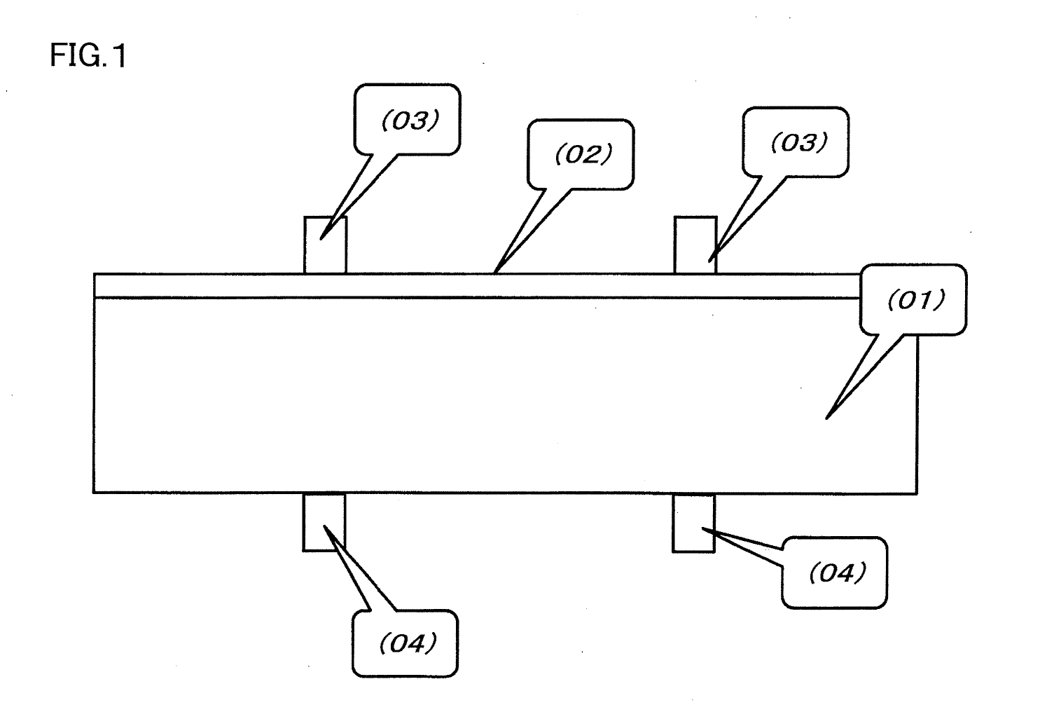

FIG. 2 is a basic illustrative diagram of a solar cell according to the present invention;

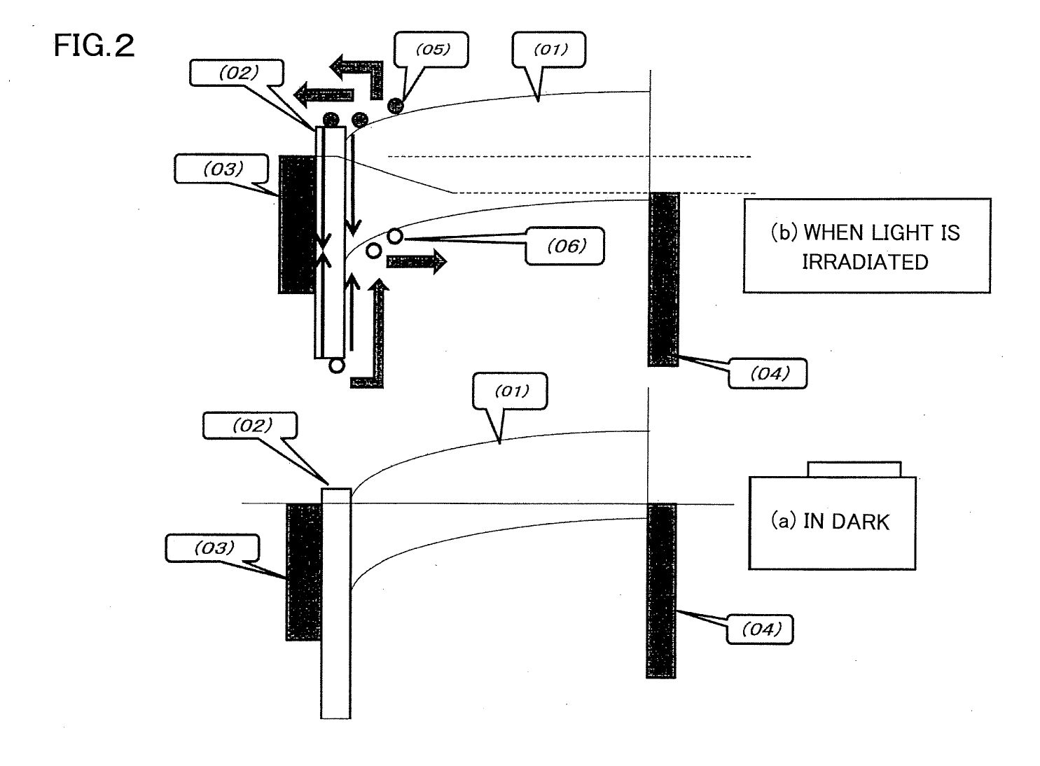

FIG. 3 is a diagram illustrating the principle of a conventional n-p junction solar cell;

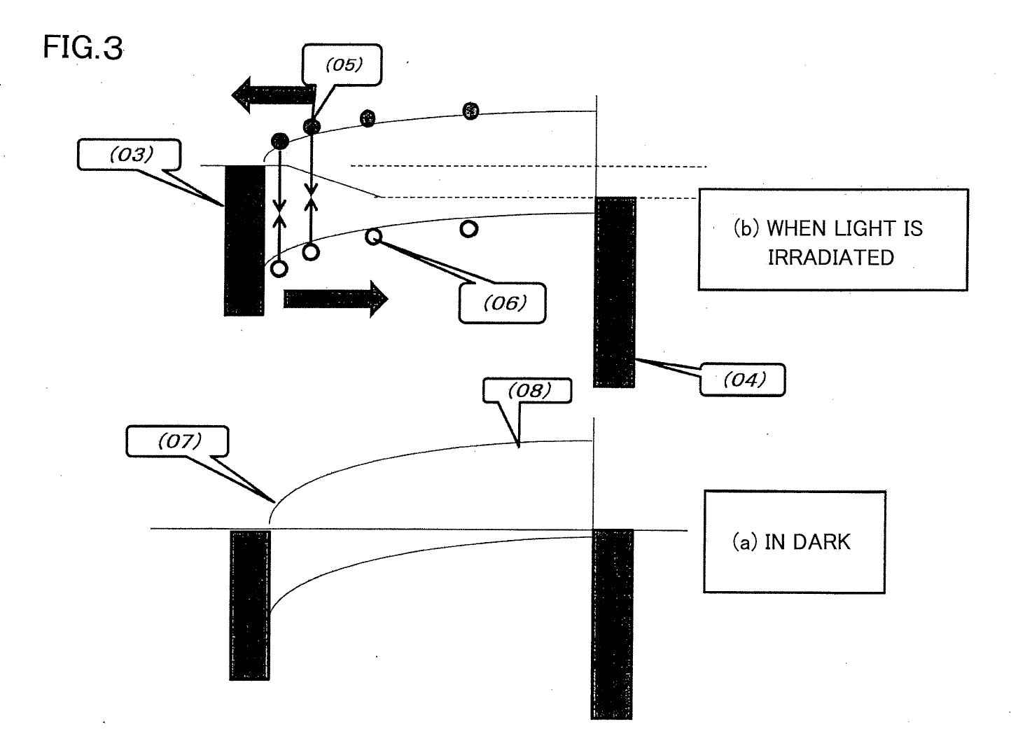

FIG. 4 is a cross sectional view of an n-type InGaP/p Ge solar cell according to the present invention;

FIG. 5 is a cross sectional view of an n-type InGaP/p Ge//n InGaAs/p InGaAs//p InGaP/n InGaP three junction solar cell according to the present invention;

FIG. 6 is a cross sectional view of an n-type GaP/p-type Si solar cell according to the present invention; and

FIG. 7 is a cross sectional view of an n-type AIN/p-type SiC solar cell according to the present invention.

### DETAILED DESCRIPTION OF THE INVENTION

### First Embodiment

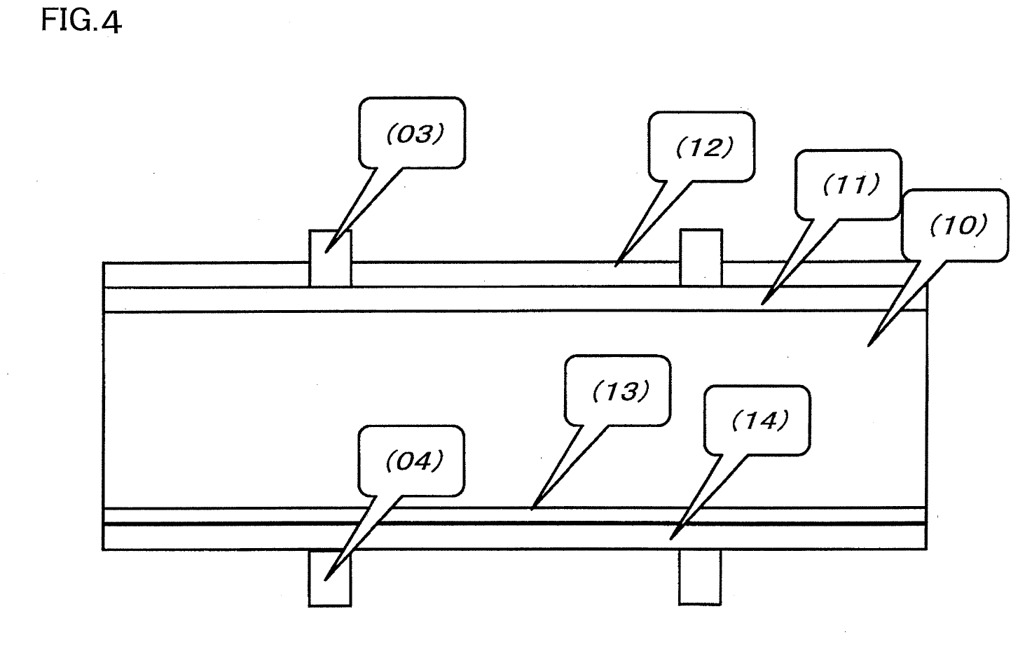

FIG. 4 shows a first embodiment of a solar cell according to the present invention.

A germanium substrate (10) is made of p-type germanium with the orientation of 100, the thickness of 200 μm and the hole carrier concentration controlled to 10¹⁸ cm⁻³. The substrate (10) is thoroughly cleaned with acid such as HF in advance. Thereafter, an n-type InGaP layer (11) is formed as an n-type semiconductor layer by the MOCVD method (Metalorganic Vapor Phase Epitaxial Growth method) at 550° C. Film thickness is 0.1 μm. In order to reduce stress due to the lattice distortion, the composition ratio of In and Ga is set to 49% and 51% respectively. The negative electrode (03) is made of AG, and the positive electrode (04) is made of AI. An anti-reflection film (12) is formed on the n-type semiconductor layer (11). (13) represents a negative electrode, and (14) represents a p-type high concentration layer.

A solar cell according to the present invention has current-voltage characteristics including the open circuit voltage of 0.705 V, the saturation current of 26 mA/cm⁻² and the fill factor of 0.75. The open circuit voltage of a solar cell according to the present invention is 0.7 V, which is much larger than the band width of a Group V germanium.

### Second Embodiment

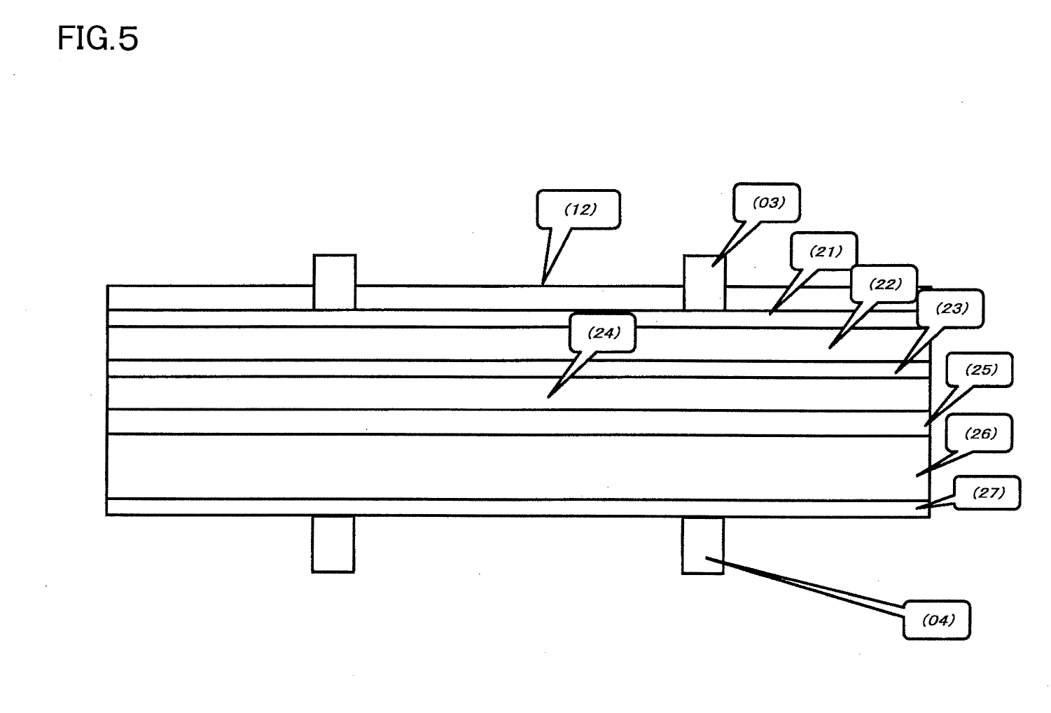

FIG. 5 shows a second embodiment of a solar cell according to the present invention.

A heterojunction solar cell has a p-n junction structure by stacking a p-type germanium substrate (26), an n-type InGaP layer (25), a homojunction p-type InGaAs layer (24), a n-type InGaAs layer (23), a homojunction p-type InGaP (22) and an n-type InGaP layer (21) in this order. Respective homojunction solar cells are bonded to each other by the tunnel junction. In addition, an anti-reflection film (12) and an ohmic electrode (27) are provided thereon.

Compared to the open circuit voltage of 2.9 V provided by a three junction solar cell comprising Ge, InGaAs and InGap, a heterojunction solar cell comprising Ge/InGaP, InGaAs and InGaP according to the present invention provides the open circuit voltage of 3.3 V, higher by 0.4 V.

### Third Embodiment

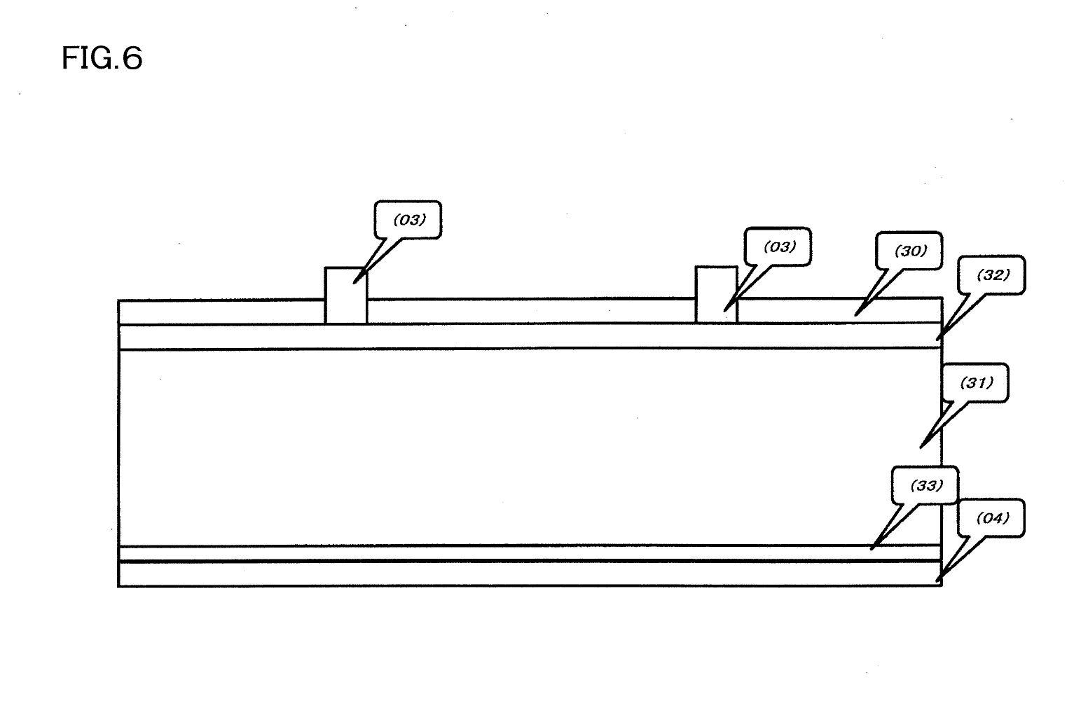

FIG. 6 shows a third embodiment of a solar cell according to the present invention.

As shown in FIG. 6, n-type GaP (32) (nitrogen doped) is grown on a p-type silicon substrate (31). The nitrogen doping level in GaP is 0.2%, and GaP and Si are lattice-matched to each other with a mismatch ratio of less than 0.1% respectively. The growth temperature is 600° C., and the liquid phase growth method is used. A negative electrode (03) is made of Ag, and a positive electrode (04) is made of Al. An AIN film is provided as an anti-reflection layer (30), and a high concentration SiC layer (33) is formed on the back surface of the p-type silicon (31).

The open circuit voltage of a solar cell fabricated in this way is 1.1 V. On the other hand, open circuit voltage of an n-p type homojunction solar cell fabricated by diffusing phosphorous as the impurity is 0.62 V.

Here, the liquid phase growth method is used. However, the method is not limited to the liquid phase growth method, and the vapor deposition method, liquid phase growth method, molecular beam epitaxial growth method, or the like may be used.

### Fourth Embodiment

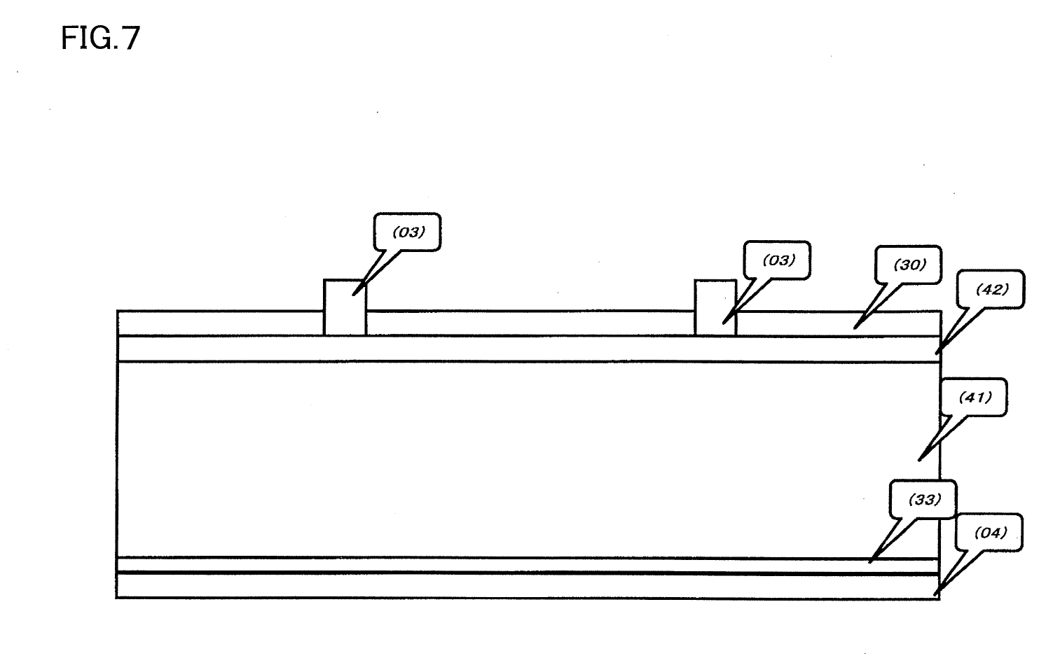

FIG. 7 shows a fourth embodiment of a solar cell according to the present invention.

In FIG. 7, n-type AIₓN (42) is formed on a p-type SiC substrate (41) having a cubic structure. p-type SiC has a carrier concentration of 10¹⁶ cm⁻³ and a band gap of 2.2 eV. n-type AIN has a carrier concentration of 10¹⁸ cm⁻³ and a thickness of 0.1 μm. AIₓN is formed by the vapor deposition method at a growth temperature of 1100° C. A negative electrode (03) is made of AI, and a positive electrode (04) is made of Ag. An AIN film is provided as an anti-reflection film (30). (33) represents a high concentration SiC layer.

The open circuit voltage of the solar cell is 2 V. Similarly, open circuit voltage of an n-p homojunction SiC solar cell fabricated by diffusing phosphorous at 1,000° C. for reference is 1.5 V.

With the structure described above, a solar cell using a semiconductor having a small band width can prevent recombining of photo-excited carriers and thereby achieve a large open circuit voltage. The open circuit voltage of conventional p-n junction solar cells is 0.27 V, while the open circuit voltage of a heterojunction solar cell according to the present invention is 0.55 to 0.71 V. Thus, a solar cell having high conversion efficiency can be obtained by increasing the open circuit voltage.

What is claimed is:

1. A heterojunction solar cell,
wherein a semiconductor A is bonded to a semiconductor B of a conductivity type different from a conductivity type of the semiconductor A and having an electron affinity a₂ which is larger than an electron affinity a₁ of the semiconductor A,
wherein the semiconductor A and the semiconductor B are lattice-matched to each other with a mismatch ratio of less than 1% respectively.

2. The heterojunction solar cell according to claim 1, wherein the semiconductor A is a Group IV semiconductor, and the semiconductor B is a Group III-V compound semiconductor.

3. The heterojunction solar cell according to claim 1, wherein the semiconductor A is a p-type indirect transition type semiconductor, and the semiconductor B is an n-type direct transition type semiconductor.

4. The heterojunction solar cell according to claim 1, wherein the semiconductor A is made of p-type germanium, and the semiconductor B is made of n-type InGaP.

5. The heterojunction solar cell according to claim 4, wherein the composition ratio of the In and the Ga is 49% and 51 respectively.

6. The heterojunction solar cell according to claim 4, wherein the hole carrier concentration of the p-type germanium is controlled to 10¹⁸ cm⁻³.

7. The heterojunction solar cell according to claim 1, wherein the semiconductor A is made of p-type silicon, and the semiconductor B is a mixed crystal made of n-type GaP as a primary component.

8. The heterojunction solar cell according to claim 7, wherein the nitrogen doping level in the GaP is 0.2%, and GaP and Si are lattice-matched to each other with a mismatch ratio of less than 0.1% respectively.

9. The heterojunction solar cell according to claim 1, wherein the semiconductor A is made of a p-type mixed crystal comprising silicon and germanium, and the semiconductor B is made of a mixed crystal of n-type compound semiconductors.

10. The heterojunction solar cell according to claim 1, wherein the semiconductor A is formed by p-type silicon carbide with n-type AIN formed on the surface thereof.

11. The heterojunction solar cell according to claim 1, wherein the semiconductor A is made of p-type silicon with a p-type germanium layer formed on the surface thereof, and n-type GaP is formed after removing an oxide film by removing the germanium layer.

12. A method for fabricating a heterojunction solar cell, in which a semiconductor A is bonded to a semiconductor B of a conductivity type different from a conductivity type of the semiconductor A and having an electron affinity a₂ which is larger than an electron affinity a₁ of the semiconductor A, and the semiconductor A and the semiconductor B are lattice-matched to each other with a mismatch ratio of less than 1% respectively,
the method comprising the steps of:
making the semiconductor A of p-type silicon with a p-type germanium layer formed on the surface thereof; and
forming n-type GaP after removing an oxide film by removing the germanium layer.

13. The method for fabricating a heterojunction solar cell according to claim 12, wherein the semiconductor A is made of p-type silicon, and the semiconductor B is a mixed crystal made of n-type GaP as a primary component.

14. The method for fabricating a heterojunction solar cell according to claim 13, wherein the nitrogen doping level in GaP is 0.2%, and GaP and Si are lattice-matched to each other with a mismatch ratio of less than 0.1% respectively.

15. The method for fabricating a heterojunction solar cell according to claim 12, wherein the semiconductor A is made of p-type silicon carbide with n-type AIN formed on the surface thereof.

16. The method for fabricating a heterojunction solar cell according to claim 12, wherein the semiconductor A is made of p-type silicon with a p-type germanium layer formed on the surface thereof, and n-type GaP is formed after removing an oxide film by removing the germanium layer.
